(19) United States
(12) Patent Application Publication
(10) Pub. No.: US 2024/0276711 A1
(43) Pub. Date: Aug. 15, 2024

(54) SEMICONDUCTOR DEVICES

(71) Applicant: Samsung Electronics Co., Ltd., Suwon-si (KR)

(72) Inventors: Yurim Kim, Suwon-si (KR); Seunghee Lee, Suwon-si (KR); Seungwoo Jang, Suwon-si (KR); Yongsuk Tak, Suwon-si (KR)

(21) Appl. No.: 18/380,848

(22) Filed: Oct. 17, 2023

(30) Foreign Application Priority Data
Feb. 15, 2023 (KR) 10-2023-0019717

(51) Int. Cl. H10B 12/00

(52) U.S. Cl. CPC H10B 12/482; H10B 12/0335; H10B 12/315

(57) ABSTRACT

The semiconductor device may include a bit line on a substrate, a gate electrode on the bit line, a gate insulation pattern on a sidewall of the gate electrode, a first channel contacting an upper surface of the bit line and the sidewall of the gate insulation pattern and a contact plug contacting an upper surface of the first channel. The first channel may include a spinel IGZO.

### CROSS-REFERENCE TO RELATED APPLICATION

This application claims priority under 35 U.S.C. § 119 to Korean Patent Application No. 10-2023-0019717 filed on Feb. 15, 2023, in the Korean Intellectual Property Office, the disclosure of which is hereby incorporated by reference in its entirety.

### TECHNICAL FIELD

The inventive concepts relate to a semiconductor device. More particularly, the inventive concepts relate to a memory device including a vertical channel.

### DISCUSSION OF RELATED ART

In order to improve a degree of integration of semiconductor devices, memory devices including vertical channel transistors have been developed, and recently, an oxide semiconductor material has been used as channels of the vertical channel transistors. The oxide semiconductor material is mainly used in an amorphous state, and has an advantage of high electron mobility. However, the oxide semiconductor material has a disadvantage in that a chemical reduction action occurs at a low energy level, and a lot of oxygen vacancies are generated.

### SUMMARY

Example embodiments provide a semiconductor device having improved characteristics.

According to example embodiments, there is provided a semiconductor device. The semiconductor device may include a bit line on a substrate, a gate electrode on the bit line, a gate insulation pattern on a sidewall of the gate electrode, a first channel contacting an upper surface of the bit line and the sidewall of the gate insulation pattern and a contact plug contacting an upper surface of the first channel. The first channel may include a spinel IGZO.

According to example embodiments, there is provided a semiconductor device. The semiconductor device may include a bit line on a substrate, a gate electrode on the bit line, a gate insulation pattern on a sidewall of the gate electrode, a channel structure and a contact plug contacting an upper surface of the channel structure. The channel structure may include a first channel, which may contact an upper surface of the bit line and the sidewall of the gate insulation pattern and include spinel IGZO, and a second channel, which may be disposed on the first channel and include a material having a lattice matching with the IGZO.

According to example embodiments, there is provided a semiconductor device. The semiconductor device may include bit lines on a substrate, gate electrodes, a gate insulation pattern on a sidewall in the first direction of each of the gate electrodes, a channel contacting upper surface of each of the bit lines and a sidewall in the first direction of the gate insulation pattern, a first channel contacting an upper portion of a sidewall of the channel in the first direction, a contact plug contacting an upper surface of the first channel and a capacitor on the contact plug. The bit lines may each extend in a first direction substantially parallel to an upper surface of the substrate, and may be spaced apart from each other in a second direction, which is substantially parallel to the upper surface of the substrate and intersects the first direction. The gate electrodes may each extend in the second direction on the bit lines and may be spaced apart from each other in the first direction. The channel may include an amorphous oxide semiconductor material. The first channel may include a spinel IGZO.

In the method of manufacturing the semiconductor device in accordance with example embodiments, the sacrificial channel layer including a material having a lattice matching with a material included in the channel layer, e.g., an amorphous IGZO, which may include GZO, may be formed on the channel layer, and a heat treatment process may be performed on the sacrificial channel layer. Thus, the amorphous IGZO included in the channel layer may be crystallized so that the channel may be formed to include, for example, a crystalline IGZO such as spinel IGZO.

The sacrificial channel layer may be subsequently removed by a cleaning process, so that a space for forming the gate electrode and the gate insulation pattern may not be reduced even though the channel may be formed to include the crystalline IGZO. Thus, the degree of integration of the semiconductor device may be improved.

In addition, as the channel includes a crystalline IGZO instead of an amorphous IGZO, the generation of oxygen vacancies therein may be reduced, and deterioration of a transistor including the channel may be reduced because a probability of hydrogen attack is low. As the channel includes a spinel IGZO, the channel may have a high mobility and high on-current characteristics.

### BRIEF DESCRIPTION OF THE DRAWINGS

FIGS. 1 to 3 are plan views and cross-sectional views illustrating a semiconductor device in accordance with example embodiments.

FIGS. 4 to 25 are plan views and cross-sectional views illustrating a method of manufacturing a semiconductor device in accordance with example embodiments.

FIG. 26 is a plan view illustrating a semiconductor device in accordance with example embodiments.

### DETAILED DESCRIPTION

The above and other aspects and features of semiconductor devices and methods of manufacturing the same in accordance with example embodiments will become readily understood from detail descriptions that follow, with reference to the accompanying drawings. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably for each material, layer, region, electrode, pad, pattern, structure or process respectively.

Hereinafter, two directions crossing each other among horizontal directions substantially parallel to an upper surface of a substrate may be referred to as first and second directions D1 and D2, respectively, and a vertical direction substantially perpendicular to the upper surface of the substrate may be referred to as a third direction D3. In example embodiments, the first and second directions may be substantially perpendicular to each other.

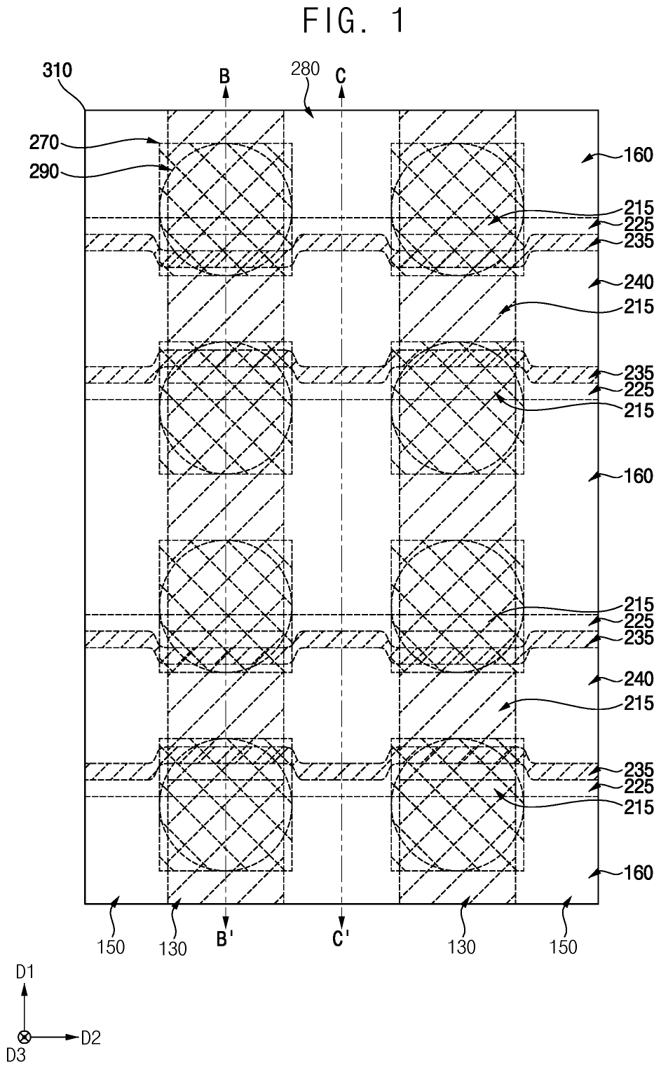

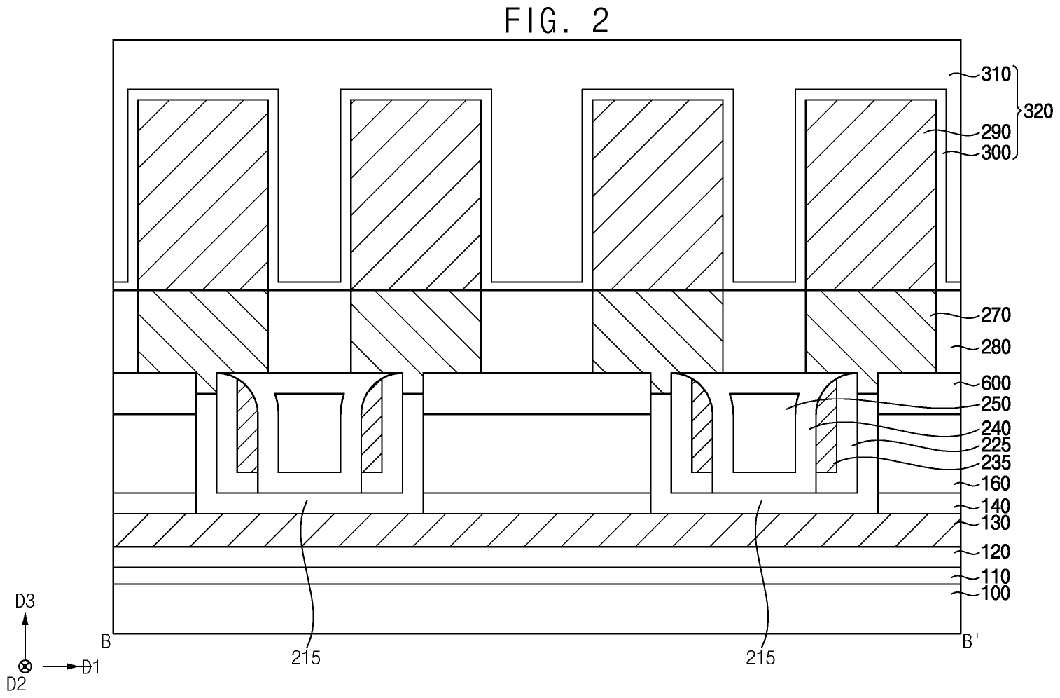

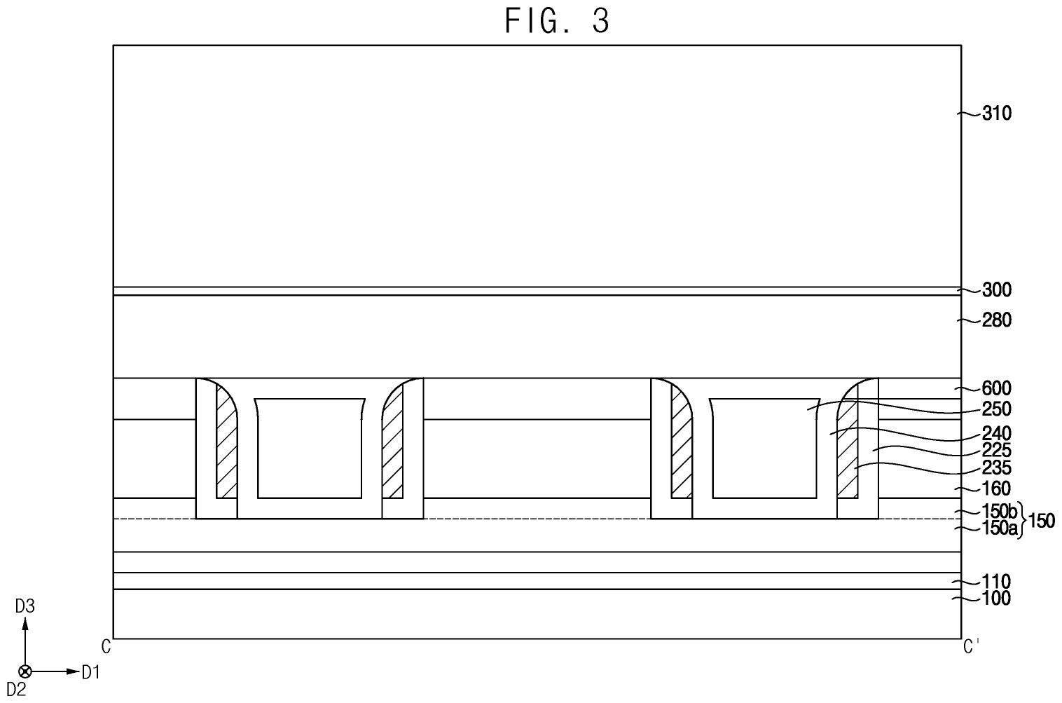

FIGS. 1 to 3 are a plan view and cross-sectional views illustrating a semiconductor device in accordance with example embodiments. FIG. 2 is a cross-sectional view taken along a line B-B′ of FIG. 1, and FIG. 3 is a cross-sectional view taken along a line C-C′ of FIG. 1.

Referring to FIGS. 1 to 3, the semiconductor device may include a bit line structure, a gate electrode 235, a gate insulation pattern 225, a first channel 215, a contact plug 270, and a capacitor 320 on a substrate 100.

In addition, the semiconductor device may further include a first insulation layer 110, a fourth insulation pattern 240, an etch stop pattern 600, and first to fourth insulating interlayer patterns 150, 160, 250 and 280.

The substrate 100 may include a semiconductor material, an insulating material or a conductive material.

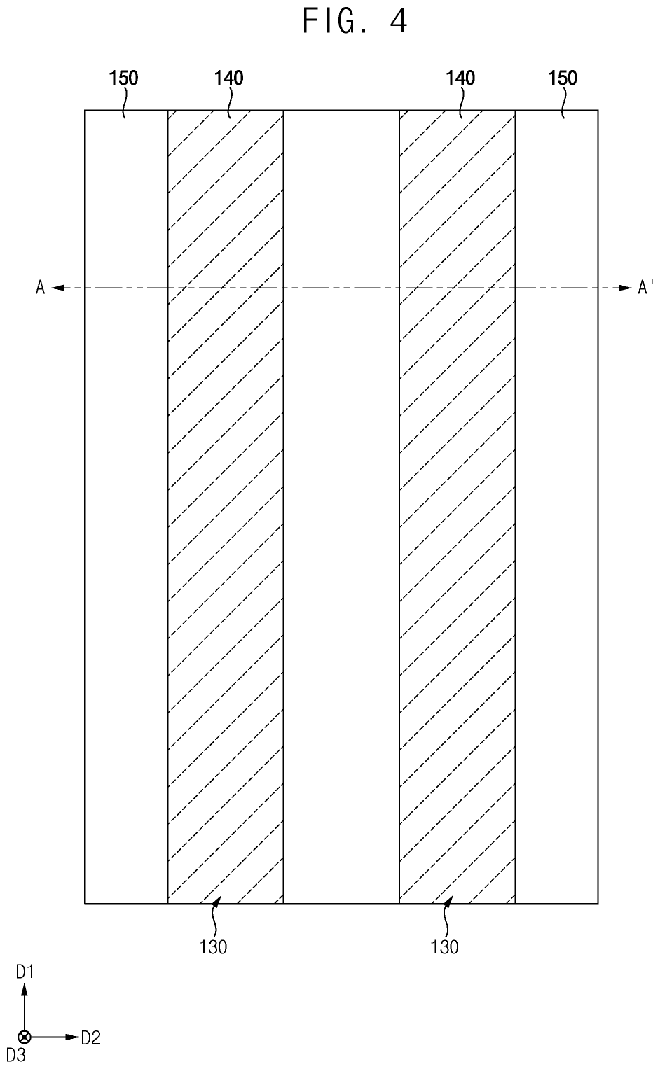

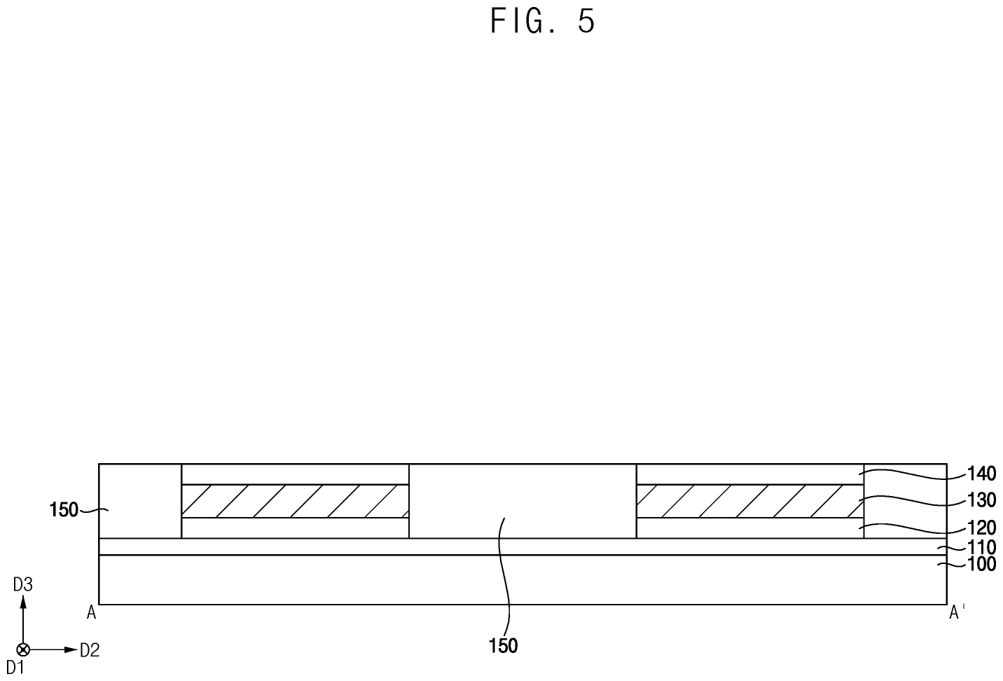

Referring to FIGS. 1 to 3 together with FIGS. 4 and 5, the first insulation layer 110 may be disposed on the substrate 100, and the bit line structure may extend in the first direction D1 on the first insulation layer 110.

In example embodiments, the bit line structure may include a second insulation pattern 120, a bit line 130, and a third insulation pattern 140 sequentially stacked on the first insulation layer 110 in the third direction D3. Each of the second insulation pattern 120 and the bit line 130 may extend in the first direction D1, and a plurality of third insulation patterns 140 may be spaced apart from each other in the first direction D1 on the bit line 130.

A plurality of bit line structures may be spaced apart from each other in the second direction D2, and the first insulating interlayer pattern 150 may extend in the first direction D1 on the first insulation layer 110 between the bit line structures neighboring in the second direction D2.

A first portion of the first insulating interlayer pattern 150 adjacent to the third insulation pattern 140 in the second direction D2 may have an upper surface higher than an upper surface of a second portion of the first insulating interlayer pattern 150 adjacent to the first channel 215 in the second direction D2. An upper portion of the first portion of the first insulating interlayer pattern 150 may be disposed at substantially the same level as a level of the third insulation pattern 140, and thus the upper surface of the first portion of the first insulating interlayer pattern 150 may be substantially coplanar with an upper surface of the third insulation pattern 140. The upper surface of the second portion of the first insulating interlayer pattern 150 may be substantially coplanar with an upper surface of the bit line 130.

As a plurality of third insulation patterns 140 is spaced apart from each other in the first direction D1, a plurality of first portions of the first insulating interlayer pattern 150 may also be spaced apart from each other in the first direction D1. Thus, the first and second portions of the first insulating interlayer pattern 150 may be alternately and repeatedly disposed in the first direction D1, and a height of the upper surface of the first insulating interlayer pattern 150 may periodically vary in the first direction D1.

Each of the first insulation layer 110 and the first insulating interlayer pattern 150 may include an oxide, e.g., silicon oxide, the bit line 130 may include a conductive material, e.g., a metal, a metal nitride or a metal silicide, and the second and third insulation patterns 120 and 140 may include an insulating nitride, e.g., silicon nitride.

The second insulating interlayer pattern 160 and the etch stop pattern 600, each of which may extend in the second direction D2, may be stacked on the third insulation pattern 140 and the first portion of the first insulating interlayer pattern 150. Hereinafter, the third insulation pattern 140, the upper portion of the first portion of the first insulating interlayer pattern 150, and the second insulating interlayer pattern 160 and the etch stop pattern thereon may be referred to as an insulation structure. In example embodiments, the insulation structure may extend in the second direction D2, and a plurality of insulation structures may be spaced apart from each other in the first direction D1.

The second insulating interlayer pattern 160 may include an oxide, e.g., silicon oxide, and the etch stop pattern 600 may include an insulating nitride, e.g., silicon nitride.

The third insulating interlayer pattern 250 extending in the second direction D2 and the fourth insulation pattern 240 surrounding the third insulating interlayer pattern 250 may be disposed between the insulation structures neighboring in the first direction D1, and the first channel 215, the gate insulation pattern 225 and the gate electrode 235 may be sequentially stacked in the first direction D1 between the insulation structure and the fourth insulation pattern 240.

The first channel 215 may contact the upper surface of the bit line 130 and sidewalls of the insulation structures neighboring in the first direction D1. In example embodiments, a plurality of first channels 215 may be spaced apart from each other in the first direction D1 by the insulation structure on each of the bit lines 130. Additionally, a plurality of first channels 215 may be spaced apart from each other in the second direction D2 by the insulation structure and the gate insulation pattern 225.

In example embodiments, the first channel 215 may include a horizontal portion with a lower surface contacting the upper surface of the bit line 130, and a vertical portion on the horizontal portion, which may have an outer sidewall contacting a sidewall of the insulation structure and a sidewall of the etch stop pattern 600. Thus, in example embodiments, a cross-section of the first channel 215 in the first direction D1 may have a cup shape.

In example embodiments, the first channel 215 may have a top surface lower than an upper surface of the etch stop pattern 600.

The first channel 215 may include an amorphous, polycrystalline or monocrystalline oxide semiconductor material. For example, first channel 215 may be a crystalline e.g. polycrystalline or protocrystalline semiconductor material. In example embodiments, the first channel 215 may include crystalline indium gallium zinc oxide (IGZO), e.g., spinel IGZO.

In another example embodiments, the first channel 215 may include indium gallium silicon oxide (IGSO), indium oxide (InOₓ, In₂O₃), tin oxide (SnO₂), titanium oxide (TiOₓ), zinc oxide nitride (ZnₓO_{y}N_{z}), magnesium zinc oxide (MgₓZn_{y}O_{z}), indium zinc oxide (InₓZn_{y}Oₐ), indium gallium zinc oxide (InₓGa_{y}Zn_{z}Oₐ), zirconium indium zinc oxide (ZrₓIn_{y}Zn_{z}Oₐ), hafnium indium zinc oxide (HfₓIn_{y}Zn_{z}Oₐ), tin indium zinc oxide (SnₓIn_{y}Zn_{z}Oₐ), aluminum tin indium zinc oxide (AlₓSn_{y}In_{z}ZnₐO_{d}), silicon indium zinc oxide (SiₓIn_{y}Zn_{z}Oₐ), zinc tin oxide (ZnₓSn_{y}O_{z}), aluminum zinc tin oxide (AlₓZn_{y}Sn_{z}Oₐ), gallium zinc tin oxide (GaₓZn_{y}Sn_{z}Oₐ), zirconium zinc tin oxide (ZrₓZn_{y}Sn_{z}Oₐ), indium gallium silicon oxide (InGₐSiO), etc., however, above materials may be crystalline.

In an embodiment, the first channel 215 may have a thickness equal to or more than about 1 nm.

The gate insulation pattern 225 may contact an inner sidewall of the vertical portion of the first channel 215, the sidewall of the insulation structure, a lower sidewall of the contact plug 270 and a lower sidewall of the fourth insulating interlayer pattern 280. The gate insulation pattern 225 may also contact an upper surface of an edge portion in the first direction D1 of the horizontal portion of the first channel 215 and an upper surface of the lower portion 150a of the first insulating interlayer pattern 150. Accordingly, in example embodiments, a cross-section of the gate insulation pattern 225 in the first direction D1 may have an “L” shape.

The gate insulation pattern 225 may include a first portion, which may contact the inner sidewall of the vertical portion of the first channel 215 and the lower sidewall of the contact plug 270, and a second portion, which may contact the sidewall of the insulation structure and the lower sidewall of the fourth insulating interlayer pattern 280.

In example embodiments, the gate insulation pattern 225 may extend in the second direction D2. However, the gate insulation pattern 225 may not extend in a straight line in the second direction D2, but may extend in a curve in the second direction D2, in a plan view. The first portion and the second portion of the gate insulation pattern 225 may not be aligned with each other in the second direction D2 due to the first channel 215, and the first and second portions of the gate insulation pattern 225 may be alternately and repeatedly disposed in the second direction D2, so that the gate insulation pattern 225 may extend in a curve in the second direction D2.

In example embodiments, lower surfaces of the first and second portions of the gate insulation pattern 225 may be disposed at different levels from each other. That is, the first portion of the gate insulation pattern 225 may contact an upper surface of the horizontal portion of the first channel 215 on the upper surface of the bit line 130, so that the lower surface of the first portion of the gate insulation pattern 225 may be substantially coplanar with the upper surface of the horizontal portion of the first channel 215 on the upper surface of the bit line 130. The second portion of the gate insulation pattern 225 may contact an upper surface of the lower portion 150a of the first insulating interlayer pattern 150 of which an upper surface may be substantially coplanar with the upper surface of the bit line 130, so that the lower surface of the second portion of the gate insulation pattern 225 may be substantially coplanar with the upper surface of the bit line 130.

Thus, the lower surface of the first portion of the gate insulation pattern 225 may be higher than the lower surface of the second portion thereof. Thus, a height of the lower surface of the gate insulation pattern 225 may not be constant, but may vary periodically in the second direction D2.

In example embodiments, a top surface of the gate insulation pattern 225 may be higher than the top surface of the first channel 215. The gate insulation pattern 225 may include an oxide, e.g., silicon oxide.

The gate electrode 235 may be disposed on the gate insulation pattern 225, and a sidewall and a lower surface of the gate electrode 235 may be covered by the gate insulation pattern 225. The gate electrode 235 may include a first portion on the first portion of the gate insulation pattern 225 and a second portion on the second portion of the gate insulation pattern 225.

Similarly to the gate insulation pattern 225, the gate electrode 235 may also extend in the second direction D2, however may not extend in a straight line in the second direction D2, but may extend in a curve in the first direction D1, in a plan view. The first portion and the second portion of the gate electrode 235 may not be aligned with each other in the second direction D2 due to the gate insulation pattern 225, and the first and second portions may be alternately and repeatedly disposed in the second direction D2, so that the gate insulation pattern 225 may extend in a curve in the second direction D2.

In example embodiments, lower surfaces of the first and second portions of the gate electrode 235 may be disposed at different levels from each other. The first portion of the gate electrode 235 may be disposed on the first portion of the gate insulation pattern 225, which may be disposed at a relatively higher level, and the second portion of the gate electrode 235 may be disposed on the second portion of the gate insulation pattern 225, which may be disposed at a relatively lower level, and thus the lower surface of the first portion of the gate electrode 235 may be higher than the lower surface of the second portion of the gate electrode 235. Accordingly, a height of the lower surface of the gate electrode 235 may not be constant, but may vary periodically in the second direction D2.

In example embodiments, a top surface of the gate electrode 235 may be lower than the top surface of the gate insulation pattern 225, and may be higher than the top surface of the first channel 215. The gate electrode 235 may include a conductive material, e.g., a metal, a metal nitride, or a metal silicide.

The fourth insulation pattern 240 may contact the upper surface of the horizontal portion of the first channel 215, the upper surface of the lower portion 150a of the first insulating interlayer pattern 150, an inner sidewall and an upper surface of the gate electrode 235, and an inner sidewall and the upper surface of the gate insulation pattern 225.

The third insulating interlayer pattern 250 may be disposed on the fourth insulation pattern 240, and lower and upper surfaces and a sidewall in the first direction D1 of the third insulating interlayer pattern 250 may be covered by the fourth insulation pattern 240. In example embodiments, the upper surface of the third insulating interlayer pattern 250 may be substantially coplanar with an upper surface of the etch stop layer 600.

The third insulating interlayer pattern 250 may include an oxide, e.g., silicon oxide, and the fourth insulation pattern 240 may include an insulating nitride, e.g., silicon nitride.

The contact plug 270 may be disposed on the first channel 215. In example embodiments, the contact plug 270 may contact the upper surface of the first channel 215 and the upper surface of the etch stop pattern 600, and further contact upper surfaces of portions of the gate insulation pattern 225 and the fourth insulation pattern 240 adjacent to the first channel 215. However, the contact plug 270 may not contact the upper surface of the gate electrode 235, but may be spaced apart from the upper surface of the gate electrode 235 by the fourth insulation pattern 240.

In example embodiments, the contact plug 270 may include a lower portion having a relatively narrow width and an upper portion having a relatively large width. A lower surface of the lower portion of the contact plug 270 may be lower than the upper surfaces of the fourth insulation pattern 240 and the etch stop pattern 600, and a lower surface of the upper portion of the contact plug 270 may be substantially coplanar with the upper surfaces of the fourth insulation pattern 240 and the etch stop pattern 600.

In example embodiments, a plurality of contact plugs 270 may be spaced apart from each other in the first and second directions D1 and D2, and may be arranged in a lattice pattern or honeycomb pattern in a plan view.

The contact plug 270 may include a conductive material such as a metal, a metal nitride, a metal silicide, etc.

The fourth insulating interlayer pattern 280 may be disposed on the etch stop pattern 600, the fourth insulation pattern 240 and the gate insulation pattern 225, and may cover sidewalls of the contact plug 270. The fourth insulating interlayer pattern 280 may include an insulating nitride, e.g., silicon nitride.

The capacitor 320 may include first and second capacitor electrodes 290 and 310, and a dielectric layer 300 therebetween. The first capacitor electrode 290 may be disposed on the contact plug 270, the dielectric layer 300 may be disposed on an upper surface and a sidewall of the first capacitor electrode 290 and an upper surface of the fourth insulating interlayer pattern 280, and the second capacitor electrode 310 may be disposed on the dielectric layer 300.

As a plurality of contact plugs 270 is spaced apart from each other in the first and second directions D1 and D2, a plurality of first capacitor electrodes 290 may also be spaced apart from each other in the first and second directions D1 and D2.

In example embodiments, the first capacitor electrode 290 may have a shape, e.g., a circle, an ellipse, a polygon, a polygon with rounded corners, etc., in a plan view. The first capacitor electrode 290 may be arranged in a lattice pattern or a honeycomb pattern in a plan view.

In the semiconductor device, current may flow in the third direction D3, that is, in the vertical direction, within the first channel 215 between the bit line 130 and the contact plug 270, and thus the semiconductor device may include a vertical channel transistor (VCT), which may have a vertical channel. The vertical channel transistor can be a VCT-DRAM, however materials and processes herein such as the spinel IGZO layer and sacrificial layer for lattice matching, and variations herein, can additionally be applied to other processes for making transistors, such as a method for forming a planar FET.

As described above, the first channel 215 may include a crystalline oxide semiconductor material, e.g., crystalline IGZO. Accordingly, when compared to a channel including, for example, an amorphous oxide semiconductor material, the first channel 215 may include a low oxygen vacancy and may have a low probability of hydrogen attack, thereby reducing deterioration of the VCT including the first channel 215.

In addition, the first channel 215 may include, in particular, spinel IGZO among crystalline IGZO, and thus, for example, when compared to C-Axis Aligned Crystalline (CAAC) IGZO, the first channel 215 may have a high mobility due to a low effective mass, and may have high on-current characteristics.

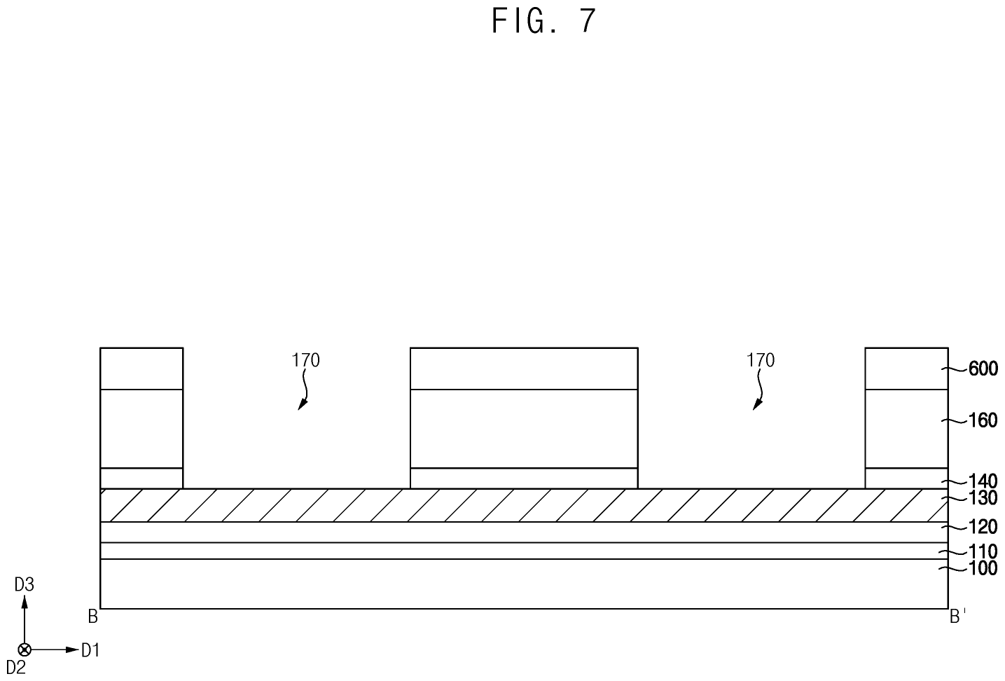

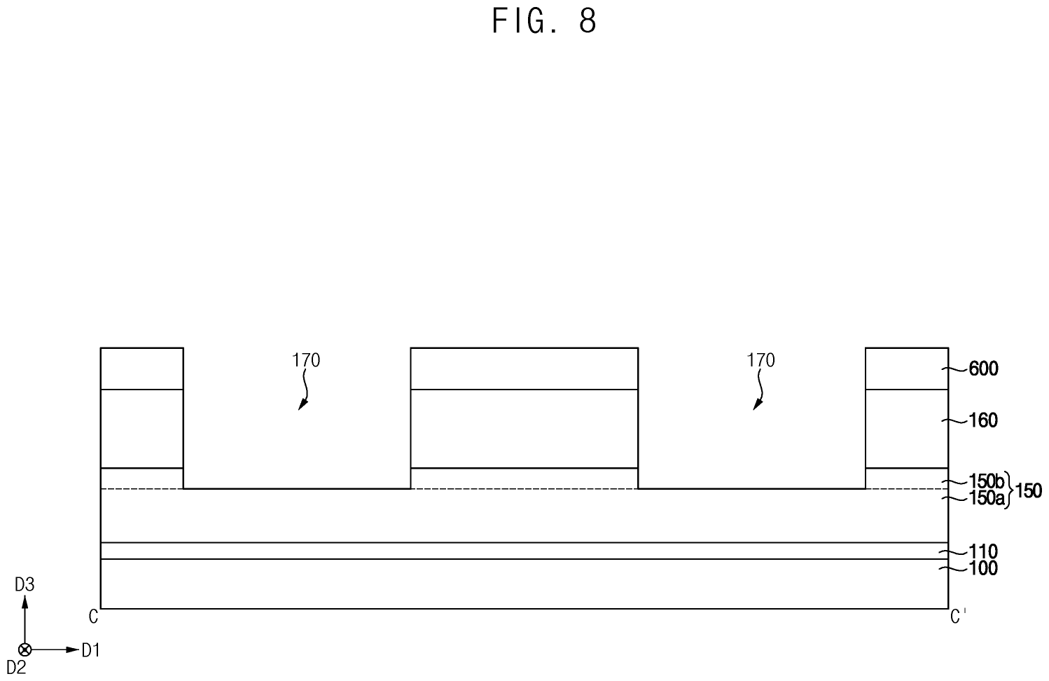

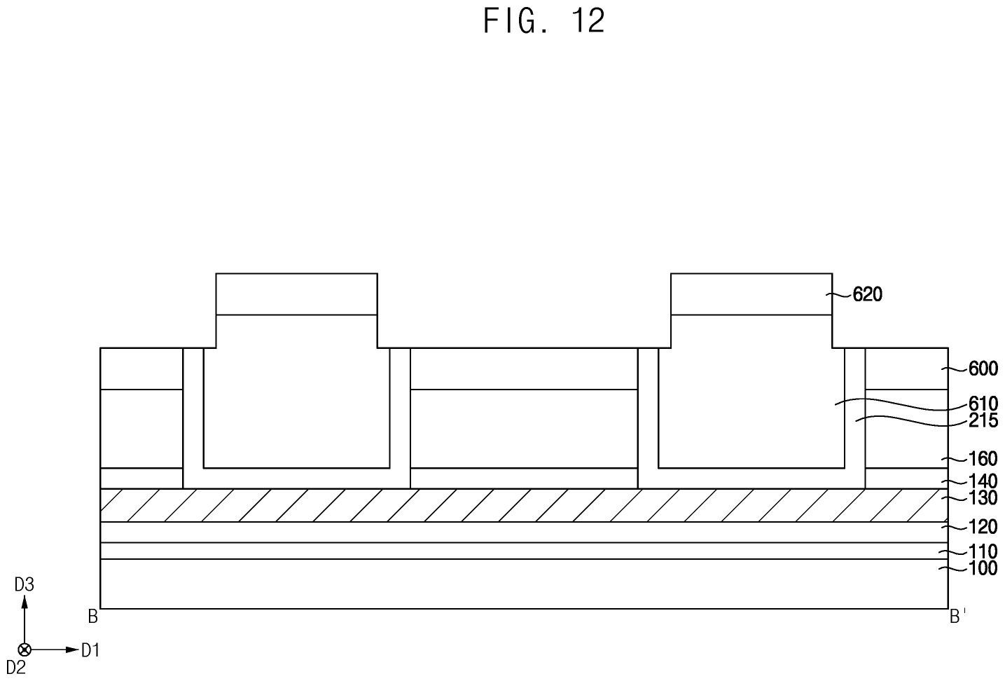

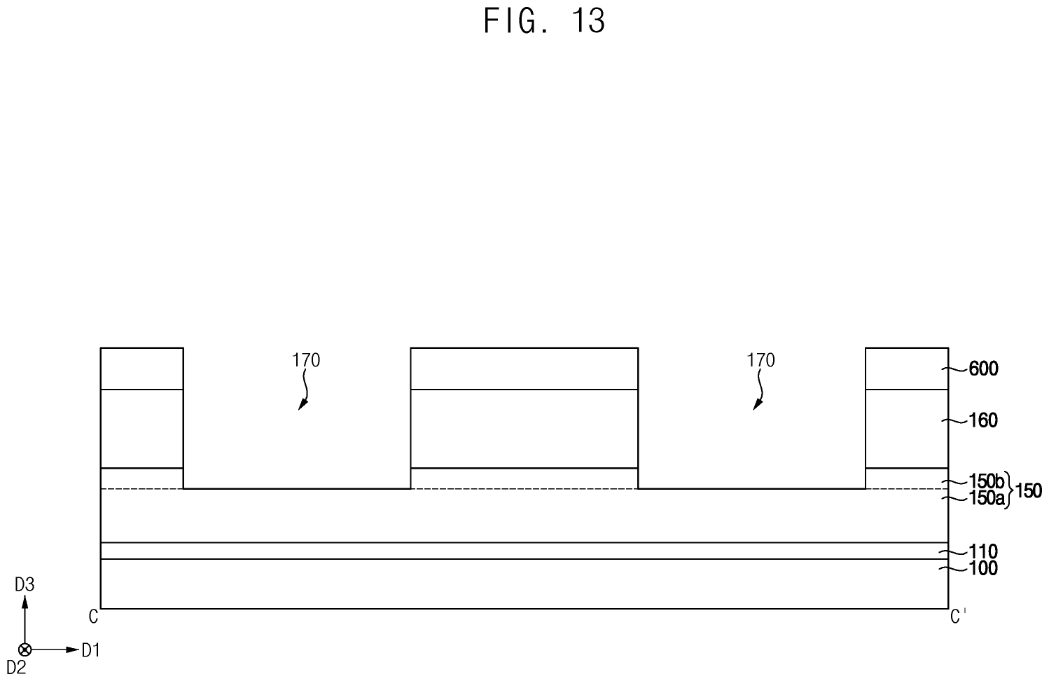

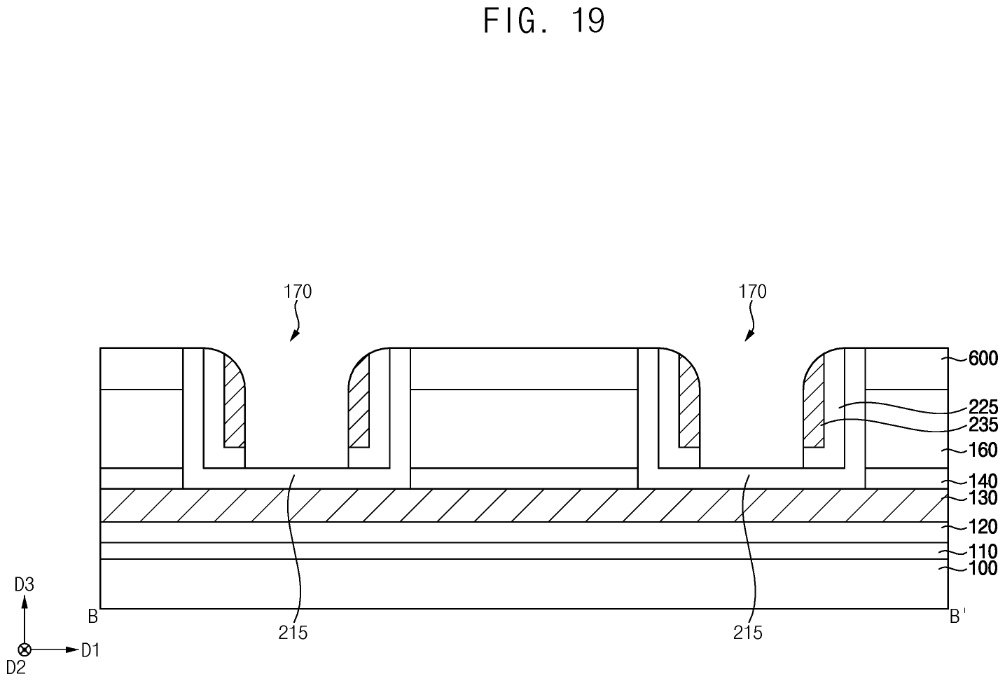

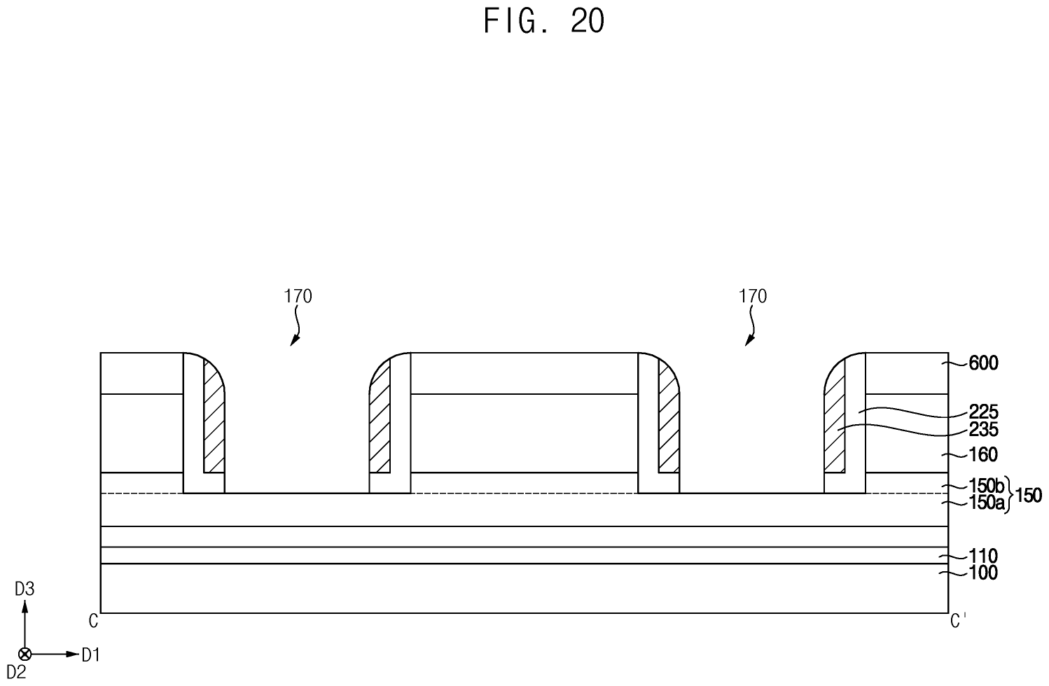

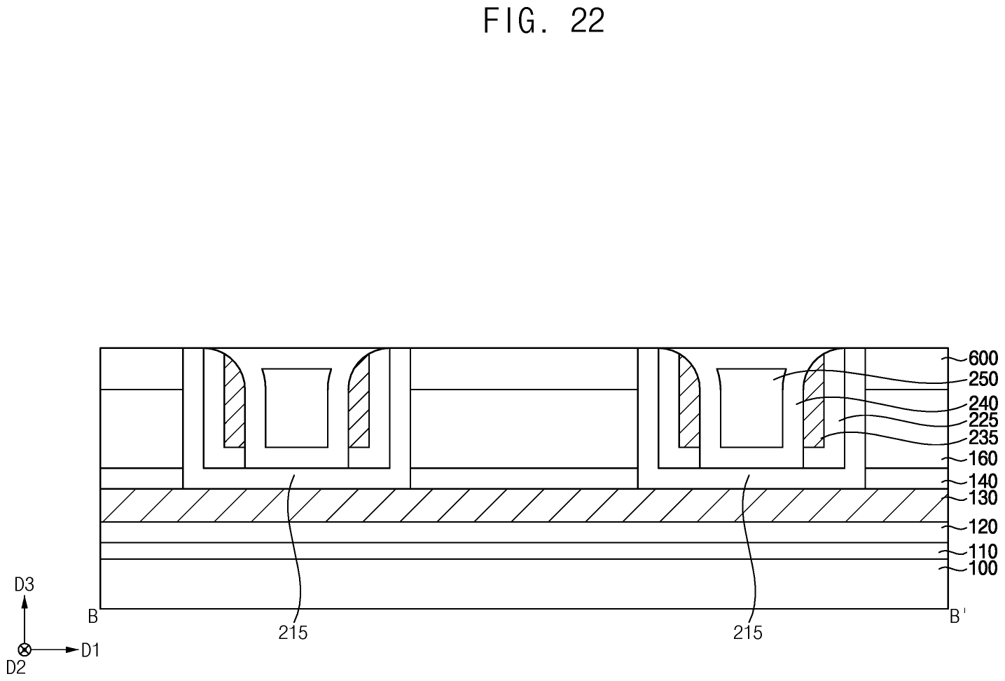

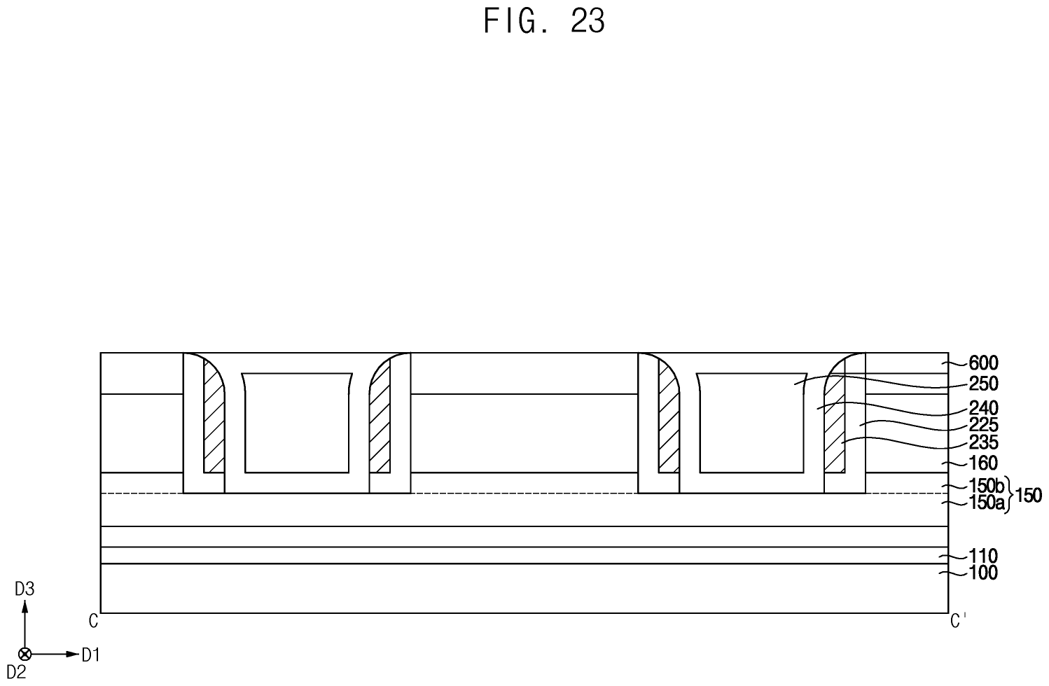

FIGS. 4 to 25 are plan views and cross-sectional views illustrating a method of manufacturing a semiconductor device in accordance with example embodiments. Specifically, FIGS. 4, 6, 11, 14, 18, 21 and 24 are the plan views, and FIG. 5 is a cross-sectional view taken along a line A-A′ of FIG. 4, FIGS. 7, 9-10, 12, 15-16, 19, 22 and 25 are cross-sectional views taken along lines B-B′ of corresponding plan views, respectively, and FIGS. 8, 13, 17, 20 and 23 are cross-sectional views taken along lines C-C′ of corresponding plan views, respectively.

Referring to FIGS. 4 and 5, a first insulation layer 110, a second insulation layer, a bit line layer, and a third insulation layer may be sequentially stacked on a substrate 100, and the third insulation layer, the bit line layer and the second insulation layer may be patterned to form a third insulation pattern 140, a bit line 130, and a second insulation pattern 120, respectively.

In example embodiments, the third insulation layer may include silicon nitride (SiN), silicon oxynitride (SiON), silicon oxycarbonitride (SiOCN), silicon oxycarbide (SiOC), etc.

The second insulation pattern 120, the bit line 130 and the third insulation pattern 140 sequentially stacked on the first insulation layer 110 may be collectively referred to as a bit line structure. In example embodiments, the bit line structure may extend in the first direction D1 on the substrate 100, and a plurality of bit line structures may be spaced apart from each other in the second direction D2. Thus, a first opening, which may expose an upper surface of the first insulation layer 110, may be formed between the bit line structures neighboring in the second direction D2.

A first insulating interlayer may be formed on the bit line structures and the first insulation layer 110 to fill the first opening, and an upper portion of the first insulating interlayer may be planarized until upper surfaces of the bit line structures are exposed to form a first insulating interlayer pattern 150 extending in the first direction D1 between the bit line structures.

In example embodiments, the planarization process may include, e.g., a chemical mechanical polishing (CMP) process and/or an etch-back process.

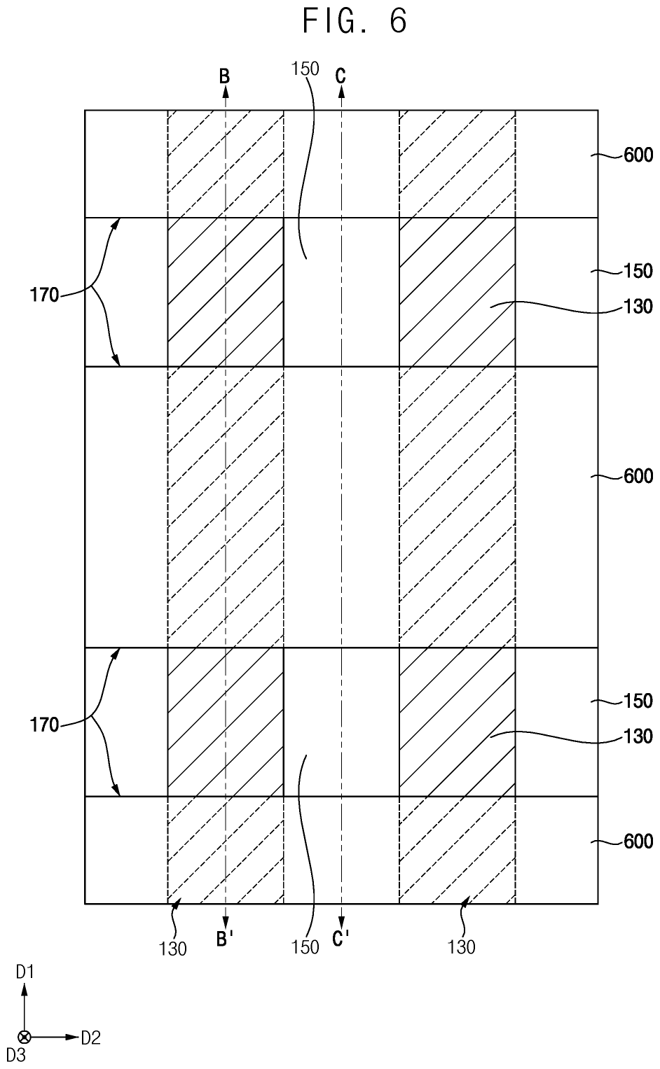

Referring to FIGS. 6 to 8, a second insulating interlayer and an etch stop layer may be sequentially formed on the bit line structures and the first insulating interlayer patterns 150, and may be partially removed by e.g., a dry etching process to form a second opening 170, which may expose upper surfaces of the third insulation pattern 140 and the first insulating interlayer pattern 150 and extend in the second direction D2.

Accordingly, the etch stop layer may be divided into a plurality of etch stop patterns 600, each of which may extend in the second direction D2, spaced apart from each other in the first direction D1, and the second insulating interlayer may be divided into a plurality of second insulating interlayer patterns 160, each of which may extend in the second direction D2, spaced apart from each other in the first direction D1.

A portion of the third insulation pattern 140, which may be exposed by the second opening 170, may be removed to divide the third insulation pattern 140, which may extend in the first direction D1, into a plurality of third insulation patterns 140 spaced apart from each other in the first direction D1, and an upper portion of the first insulating interlayer pattern 150, which may be exposed by the second opening 170, may also be removed.

Accordingly, the first insulating interlayer pattern 150 may include a lower portion 150a, which may be formed on the first insulation layer 110 at a level substantially the same as levels of the second insulation layer 120 and the bit line 130, and an upper portion 150b, which may be formed on the lower portion 150a and adjacent to the third insulation pattern 140 in the second direction D2. As the third insulation pattern 140 is divided into a plurality of third insulation patterns 140 spaced apart from each other in the first direction D1, a plurality of upper portions 150b of the first insulating interlayer pattern 150 may be spaced apart from each other in the first direction D1.

Hereinafter, the third insulation pattern 140 and the upper portion 150b of the first insulating interlayer pattern 150, and the second insulating interlayer pattern 160 and the etch stop pattern 600 sequentially stacked in the third direction D3 on the third insulation pattern 140 and the upper portion 150b of the first insulating interlayer pattern 150 may be referred to as a bar structure. In example embodiments, the bar structure may extend in the second direction D2, and a plurality of bar structures may be spaced apart from each other in the first direction D1.

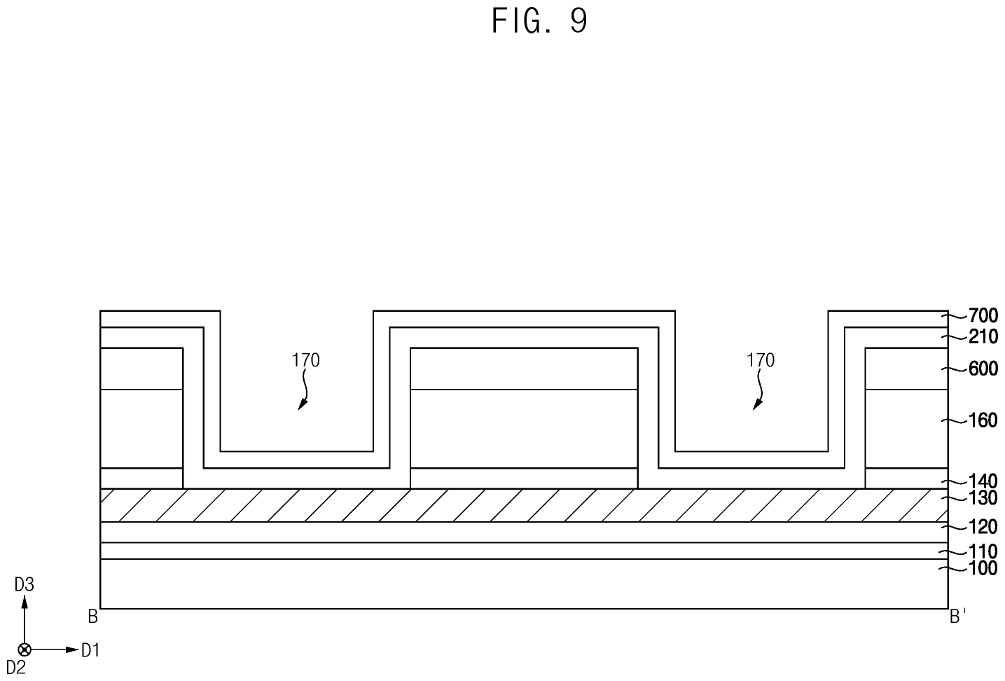

Referring to FIG. 9, a channel layer 210 and a sacrificial channel layer 700 may be formed on upper surfaces of the bit line 130 and the first insulating interlayer pattern 150, which may be exposed by the second opening 170, and a sidewall and an upper surface of the bar structure.

Each of the channel layer 210 and the sacrificial channel layer 700 may be formed by a deposition process, e.g., an ALD process, a CVD process, etc., and may include an amorphous oxide semiconductor material.

In example embodiments, the sacrificial channel layer 700 may include a material having a lattice matching with an oxide semiconductor material included in the channel layer 210.

Thus, in example embodiments, the channel layer 210 may include, e.g., IGZO, and the sacrificial channel layer 700 may include, e.g., gallium zinc oxide (GaZn₂O₄: GZO), zinc indium oxide (ZnIn₂O₄), zinc tin oxide (Zn₂SnO₄), zinc titanium oxide (Zn₂TiO₄), gallium oxide (Ga₂O₃), titanium nitride (TiN), silicon carbide (SiC), ruthenium oxide (RuO₂), zinc aluminum oxide (ZnAl₂O₄), etc.

In example embodiments, the channel layer 210 may include amorphous IGZO when the channel layer 210 is deposited. However, during the formation of the sacrificial channel layer 700 on the channel layer 210, the amorphous IGZO included in the channel layer 210 may be crystallized by a material included in the sacrificial channel layer 700, that is, a material having a lattice match with the amorphous IGZO included in the channel layer 210. Thus, in example embodiments, the amorphous IGZO included in the channel layer 210 may be crystallized to include spinel IGZO. Channel layer 210 may also be deposited as a mixed amorphous/c-axis-aligned crystalline (CAAC) film or other protocrystalline or crystalline form, which can then form a spinel (or CAAC) channel layer using a polycrystalline sacrificial layer as a template.

In an embodiment, each of the channel layer 210 and the sacrificial channel layer 700 may have a thickness equal to or more than about 1 nm.

In example embodiments, after forming the sacrificial channel layer 700 on the channel layer 210, a heat treatment process may be performed on the sacrificial channel layer 700 so as to cause or enhance crystallization of the channel layer 210. The heat treatment process may include, e.g., an annealing process using oxygen gas, and the annealing process may be performed at, e.g., about 700° C.

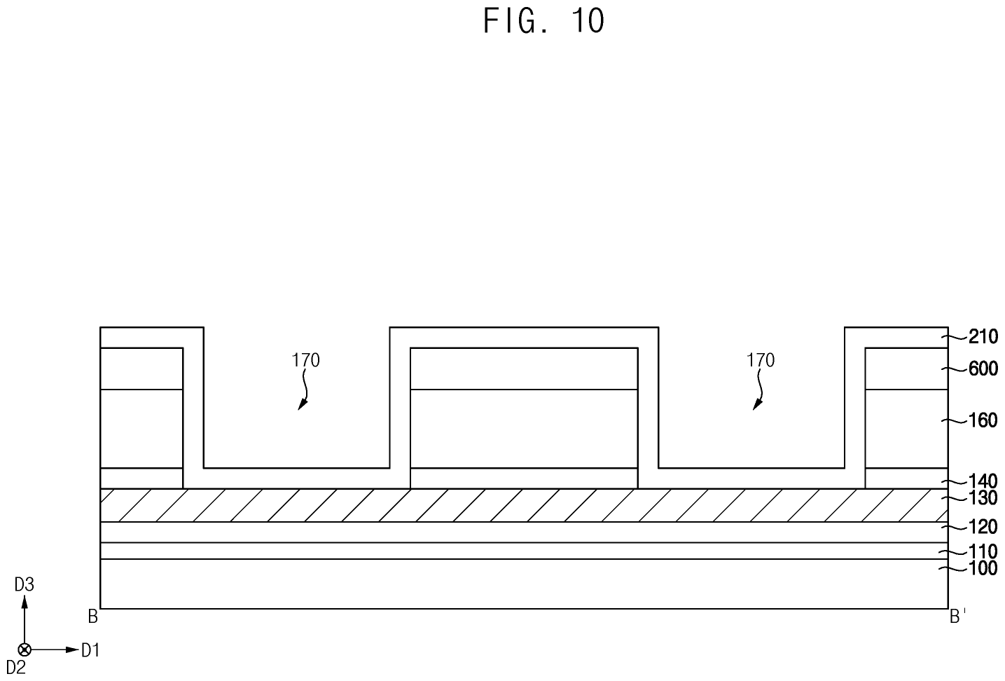

Referring to FIG. 10, the sacrificial channel layer 700 may be removed, and thus a surface of the channel layer 210 may be exposed.

The sacrificial channel layer 700 may be removed by, e.g., a cleaning process.

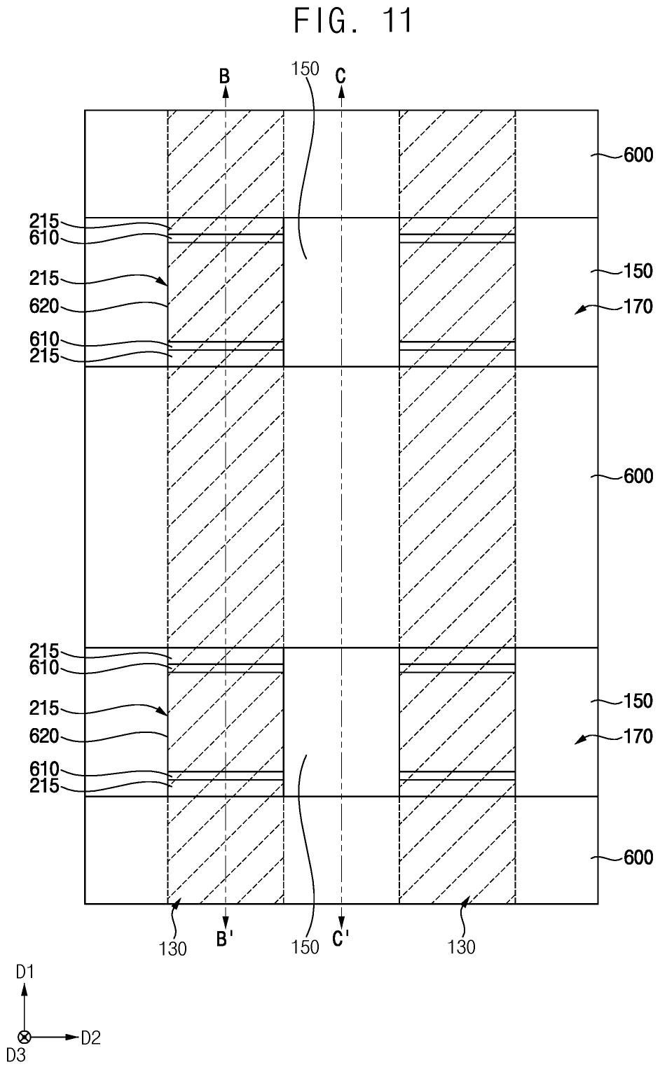

Referring to FIGS. 11 to 13, a sacrificial layer may be formed on the channel layer 210, a mask 620 may be formed on the sacrificial layer, and the sacrificial layer and the channel layer 210 may be partially removed by an etching process using the mask 620 as an etching mask, so that an upper surface of the etch stop pattern 600 and an upper surface of the first insulating interlayer pattern 150 may be exposed.

The mask 620 may include, e.g., a photoresist pattern, and the sacrificial layer may include, e.g., a spin-on-hardmask (SOH), an amorphous carbon layer (ACL), etc.

Through the etching process, the sacrificial layer and the channel layer 210 may be transformed into a sacrificial pattern 610 and a first channel 215, respectively.

In example embodiments, a plurality of masks 620 may be spaced apart from each other in the first and second directions D1 and D2, and may overlap in the third direction D3 a portion of the bit line 130 exposed by the second opening 170. Accordingly, a plurality of first channels 215 may be spaced apart from each other in the first and second directions D1 and D2 on the portion of the bit line 130 exposed by the second opening 170, and a plurality of sacrificial patterns 610 may be spaced apart from each other in the first and second directions D1 and D2 on the portion of the bit line 130 exposed by the second opening 170.

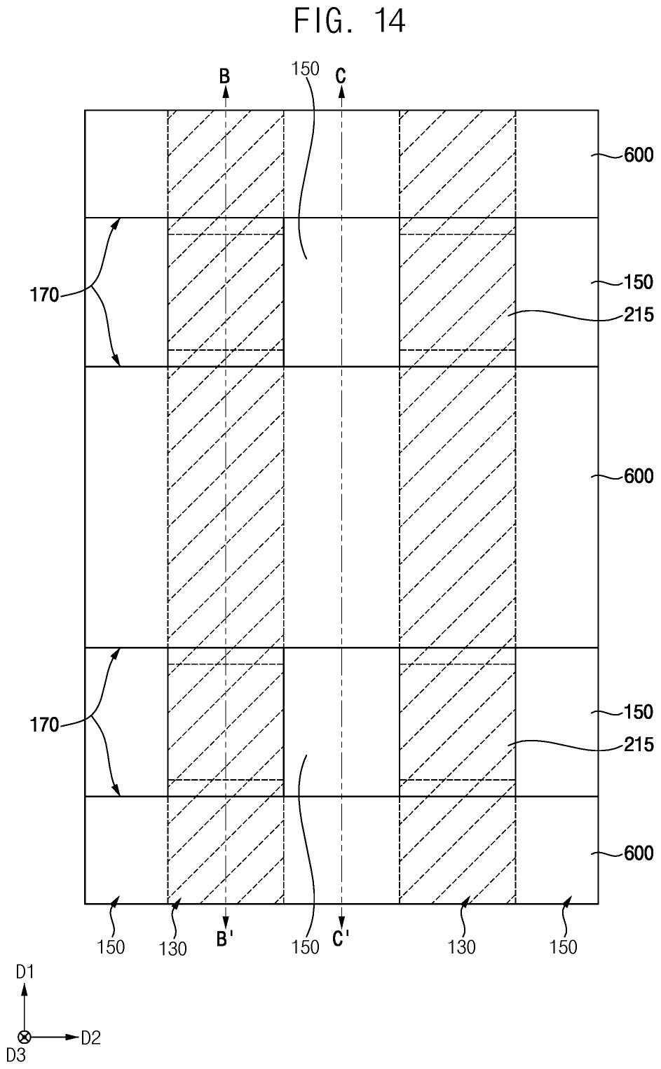

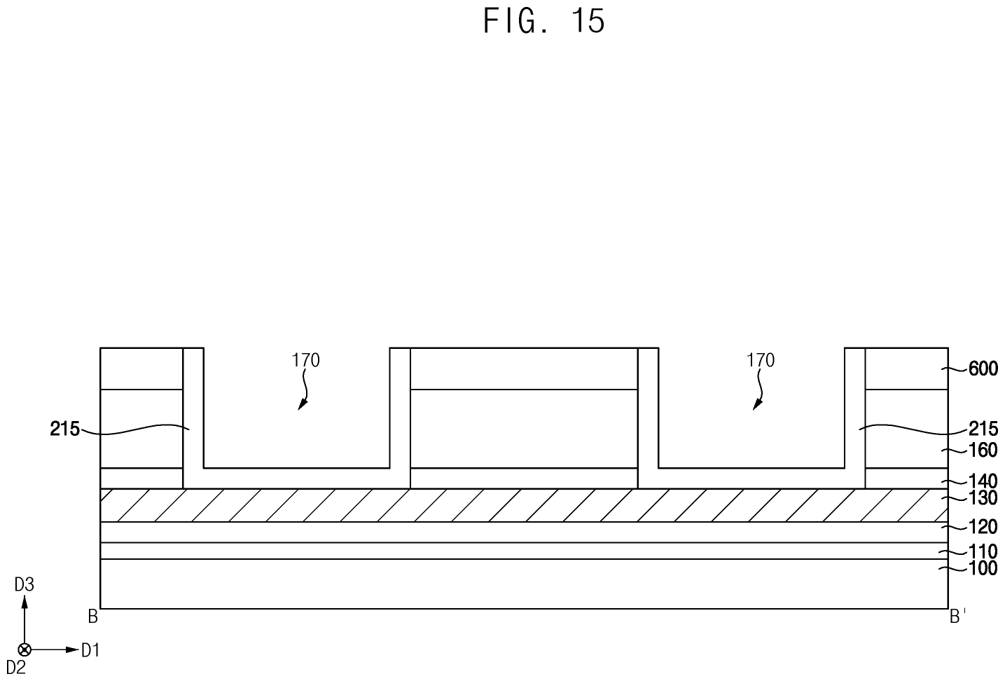

Referring to FIGS. 14 and 15, the mask 620 and the sacrificial pattern 610 may be removed by, e.g., an ashing process and/or a stripping process.

Accordingly, an upper surface of the first channel 215 may be exposed again.

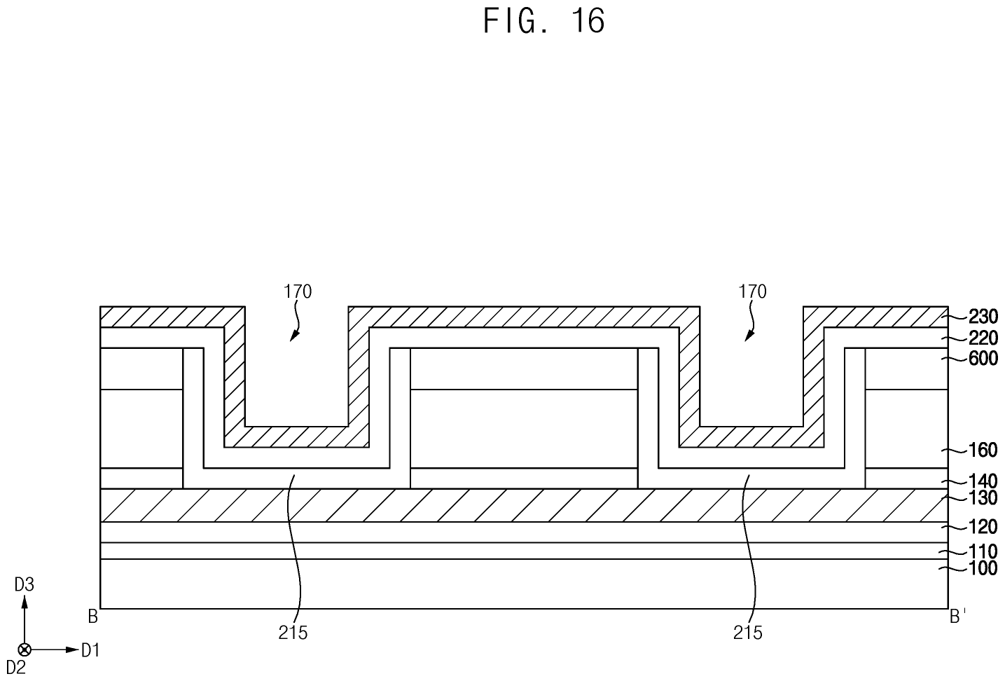

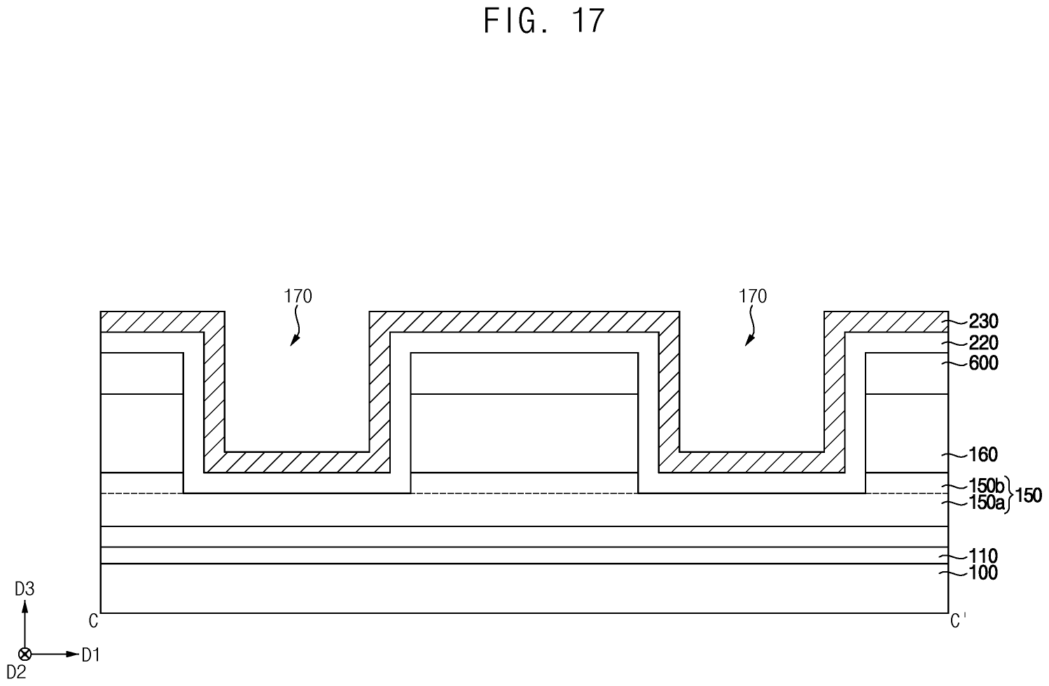

Referring to FIGS. 16 and 17, a gate insulation layer 220 and a gate electrode layer 230 may be sequentially formed on the first channel 215, the first insulating interlayer pattern 150 and the etch stop pattern 600.

In example embodiments, the gate insulation layer 220 and the gate electrode layer 230 may be formed by a deposition process, e.g., a CVD process or an ALD process.

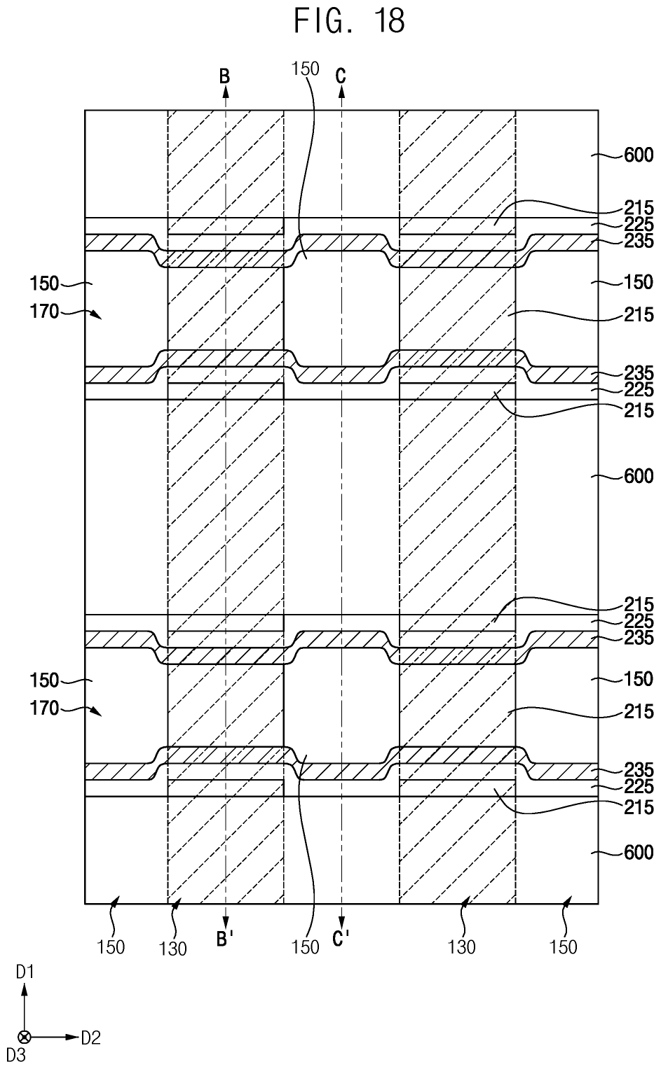

Referring to FIGS. 18 to 20, an anisotropic etching process may be performed on the gate electrode layer 230 and the gate insulation layer 220, which may be transformed into a gate electrode 235 and a gate insulation pattern 225, respectively.

In example embodiments, the gate insulation pattern 225 and the gate electrode 235 may be sequentially stacked on an inner sidewall of a portion of the first channel 215 on each of opposite sidewalls of the second opening 170 in the first direction D1 and a sidewall of the bar structure.

Hereinafter, a portion of the gate insulation pattern 225, which may contact the portion of the first channel 215 on each of opposite sidewalls of the second opening 170 in the first direction D1, may be referred to as a first portion of the gate insulation pattern 225, and a portion of the gate insulation pattern 225, which may contact the sidewall of the bar structure, may be referred to as a second portion of the gate insulation pattern 225. Also, a portion of the gate electrode 235 on the first portion of the gate insulation pattern 225 may be referred to as a first portion of the gate electrode 235, and a portion of the gate electrode 235 on the second portion of the gate insulation pattern 225 may be referred to as a second portion of the gate electrode 235.

In example embodiments, the gate insulation pattern 225 may extend in the second direction D2. However, the gate insulation pattern 225 may not extend in a straight line in the second direction D2, but may extend in a curve in the first direction D1, in a plan view. That is, the first portion and the second portion of the gate insulation pattern 225 may not be aligned with each other in the second direction D2 due to the first channel 215. As the first and second portions of the gate insulation pattern 225 are alternately and repeatedly disposed in the second direction D2, the gate insulation pattern 225 may extend in a curve in the second direction D2.

In example embodiments, lower surfaces of the first and second portions, respectively, of the gate insulation pattern 225 may be formed at different heights from each other. That is, the first portion of the gate insulation pattern 225 may contact the upper surface of the portion of the first channel 215 on the upper surface of the bit line 130, so that a lower surface of the first portion of the gate insulation pattern 225 may be substantially coplanar with the upper surface of the portion of the first channel 215 on the upper surface of the bit line 130. On the other hand, the second portion of the gate insulation pattern 225 may contact an upper surface of the lower portion 150a of the first insulating interlayer pattern 150, which may be substantially coplanar with the upper surface of the bit line 130, so that a lower surface of the second portion of the gate insulation pattern 225 may be substantially coplanar with upper surface of the lower portion 150a of the first insulating interlayer pattern 150. Accordingly, the lower surface of the first portion of the gate insulation pattern 225 may be higher than the lower surface of the second portion thereof. Thus, a height of the lower surface of the gate insulation pattern 225 may vary periodically in the second direction D2.

In example embodiments, a cross-section in the first direction D1 of each of the first and second portions of the gate insulation pattern 225 may have an “L” shape.

Similarly to the gate insulation pattern 225, the gate electrode 235 may also extend in the second direction D2, however, the gate electrode 235 may not extend in a straight line in the second direction D2, but may extend in a curve in the first direction D1. In addition, a height of a lower surface of the gate electrode 235 may vary periodically in the second direction D2.

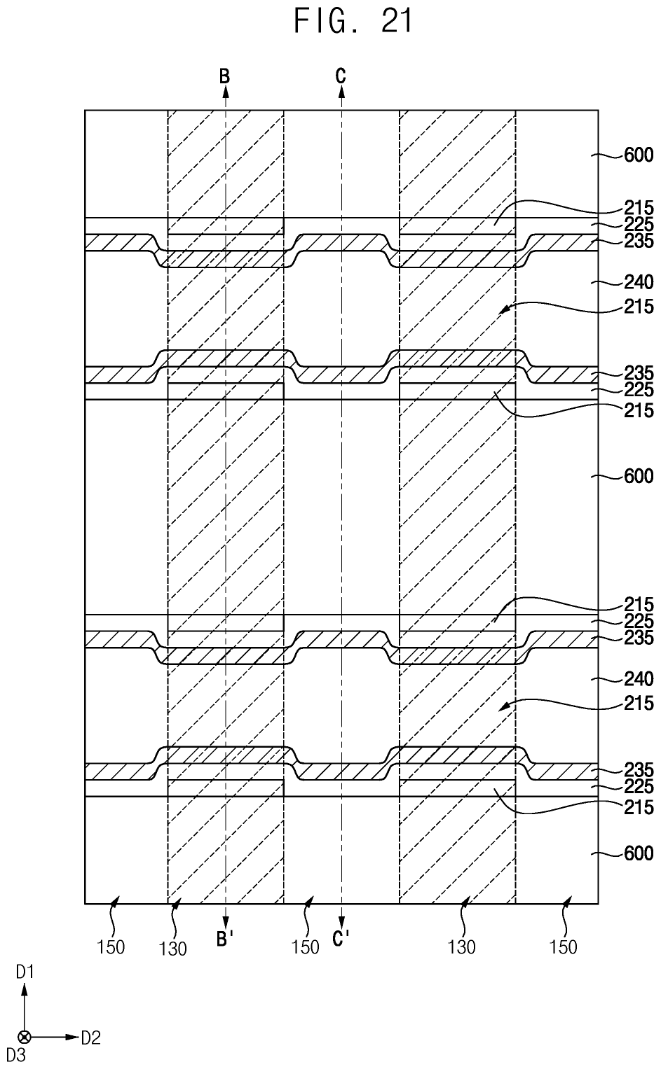

Referring to FIGS. 21 to 23, a fourth insulation layer may be formed on the first channel 215, the first insulating interlayer pattern 150, the gate insulation pattern 225, the gate electrode 235 and the etch stop pattern 600, a third insulating interlayer may be formed on the fourth insulation layer to fill a remaining portion of the second opening 170, and a planarization process may be performed on an upper portion of the third insulating interlayer and an upper portion of the fourth insulation layer until an upper surface of the etch stop pattern 600 is exposed.

In example embodiments, the planarization process may include a CMP process and/or an etch-back process. As the planarization process is performed, the third insulating interlayer and the fourth insulation layer may remain as a third insulating interlayer pattern 250 and a fourth insulation pattern 240, respectively, in the second opening 170, and each of the fourth insulation pattern 240 and the third insulating interlayer pattern 250 may extend in the second direction D2 on the first channel 215 and the first insulating interlayer pattern 150.

After forming a first recess by removing an upper portion of the third insulating interlayer pattern 250, an insulation pattern may be additionally formed in the first recess, and hereinafter, the fourth insulation pattern 240 and the additional insulation pattern in the first recess may be collectively referred to as a fourth insulation pattern 240.

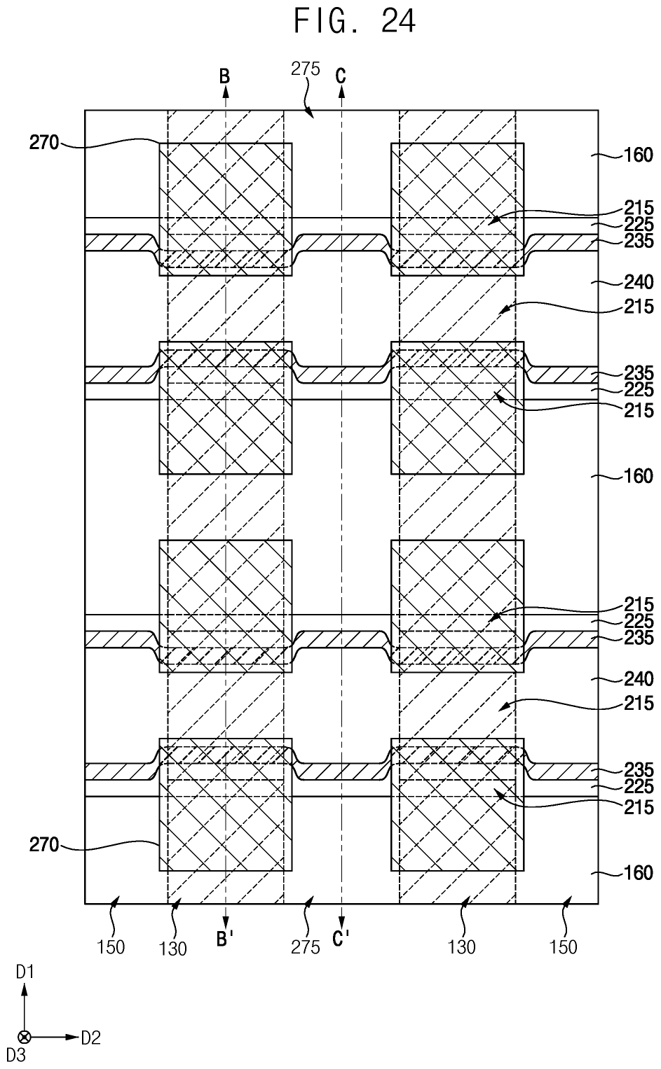

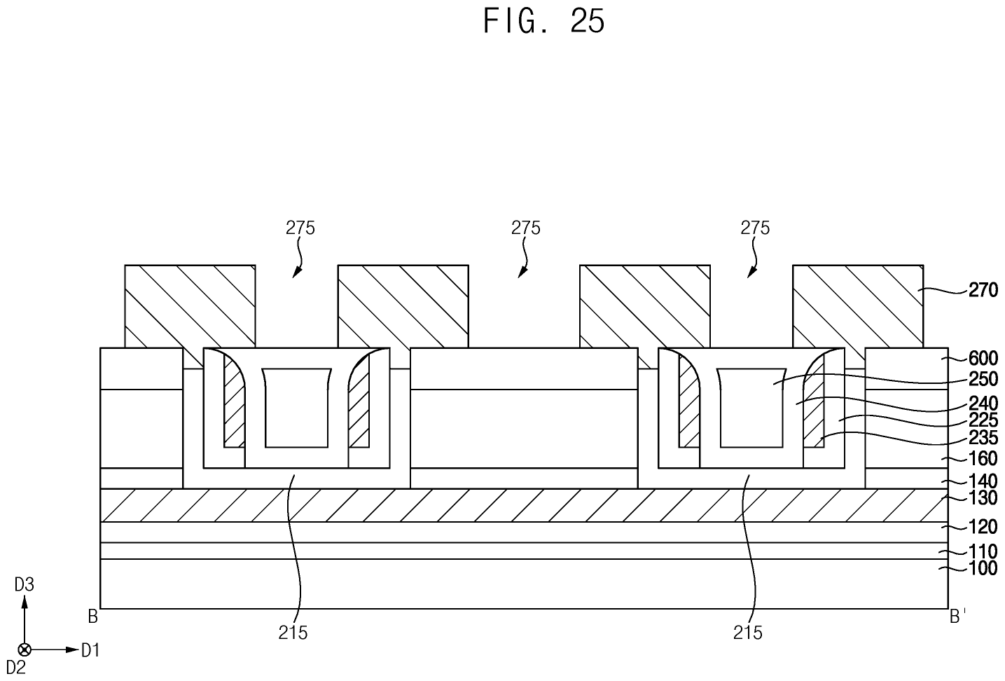

Referring to FIGS. 24 and 25, an upper portion of the first channel 215 may be partially removed by, e.g., a wet etching process to form a second recess.

A contact plug layer may be formed on the fourth insulation pattern 240, the gate insulation pattern 225, the first channel 215 and the etch stop pattern 600 to fill the second recess, and patterned to form a contact plug 270 contacting an upper surface of the first channel 215. In example embodiments, a plurality of contact plugs 270 may be spaced apart from each other in the first and second directions D1 and D2.

In an example embodiment, the contact plugs 270 may be disposed in a lattice pattern in a plan view. In another example embodiment, the contact plugs 270 may be disposed in a honeycomb pattern in a plan view.

Referring back to FIGS. 1 and 2, a fourth insulating interlayer may be formed on the fourth insulation pattern 240, the gate insulation pattern 225, the first channel 215 and the etch stop pattern 600 to cover the contact plug 270, and an upper portion of the fourth insulating interlayer may be planarized until an upper surface of the contact plug 270 is exposed, so that a fourth insulating interlayer pattern 280 may be formed to cover a sidewall of the contact plug 270.

A first capacitor electrode 290 may be formed to contact the upper surface of the contact plug 270, a dielectric layer 300 may be formed on an upper surface and a sidewall of the first capacitor electrode 290 and an upper surface of the fourth insulating interlayer pattern 280, and a second capacitor electrode 310 may be formed on an upper surface of the dielectric layer 300 to form a capacitor 320.

Accordingly, fabrication of the semiconductor device may be completed.

As illustrated above, the sacrificial channel layer 700 including, e.g., a material having a lattice which acts as a template to lattice match a material included in the channel layer 210, e.g., amorphous IGZO. The sacrificial channel layer 700, which may include e.g., GZO, may be formed on the channel layer 210, and the amorphous IGZO included in the channel layer 210 may be crystallized by a heat treatment process, so that the channel layer 210 may be formed to include crystalline IGZO, e.g., spinel IGZO.

The sacrificial channel layer 700 may be subsequently removed by a cleaning process, and thus a width of the second opening 170 reduced by the sacrificial channel layer 700 may be increased again. Thus, even though the first channel 215 includes crystalline IGZO, the width of the second opening 170 is not reduced, and thus more space may be allocated for the formation of the gate electrode 235 and the gate insulation pattern 225. As a result, a transistor including the gate electrode 235, the gate insulating pattern 225 and the first channel 215 may be formed within a relatively confined space, so that a greater quantity of semiconductor chips may be manufactured by improving the integration degree of the semiconductor device including the transistor.

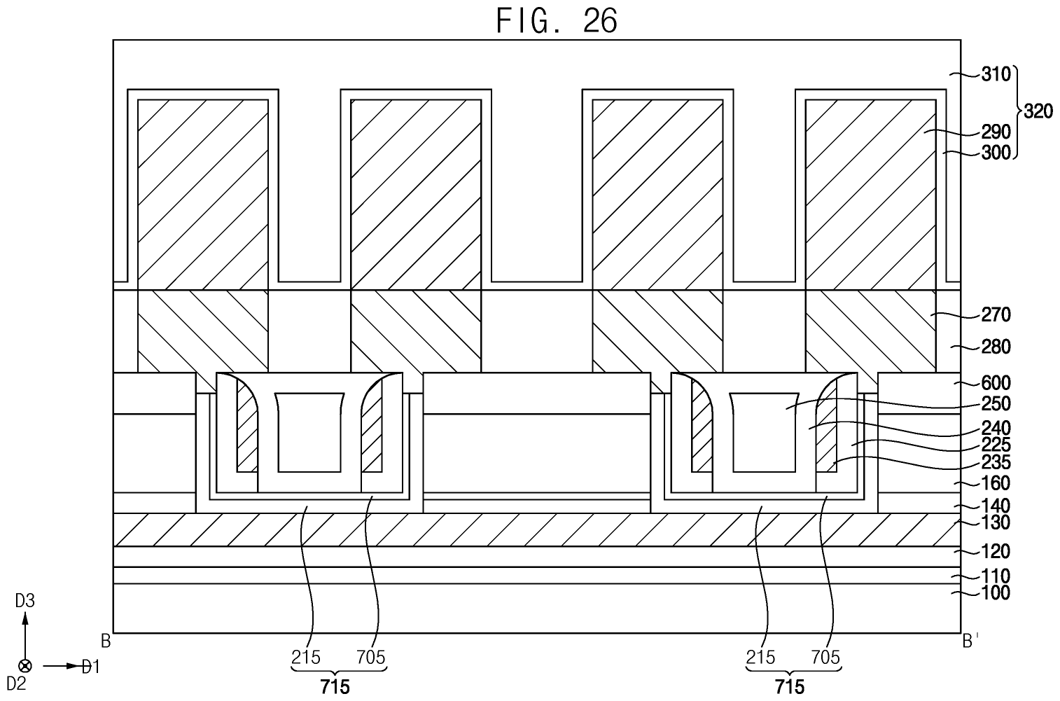

FIG. 26 is a cross-sectional view illustrating a semiconductor device in accordance with example embodiments, which may correspond to FIG. 2. The semiconductor device may be substantially the same as or similar to that of FIGS. 1 to 3, except for further including a second channel, and thus repeated explanations are omitted herein.

Referring to FIG. 26, a second channel 705 may be further formed on the first channel 215, and the first and second channels 215 and 705 may collectively form a channel structure 715.

An upper surface of each of the first and second channels 215 and 705 included in the channel structure 715 may contact the lower surface of the contact plug 270, and may be formed at substantially coplanar with each other.

When the cleaning process described with reference to FIG. 10 is performed to remove the sacrificial channel layer 700, the sacrificial channel layer 700 may not be entirely removed, but a portion, e.g., a lower portion of the sacrificial channel layer 700 may remain to form the second channel 705. For example, the sacrificial channel layer 700 may be partially or substantially removed, for example more than half of the sacrificial channel layer 700 is removed, such as 80% or more is removed, or even substantially all of the sacrificial channel layer 700 is removed leaving small or trace amounts of sacrificial channel layer material on the channel layer 210 followed by deposition of additional layers. Alternatively, the sacrificial channel layer 700 may remain as the second channel 705 by not performing the cleaning process described with reference to FIG. 10. Whether the sacrificial channel layer 700 is fully, partially or not removed, the final semiconductor device may have a first channel layer 215 having e.g., an IGZO layer, and is in the absence of a GZO or other lattice matching layer between the IGZO layer and the bit line 130.

Thus, the second channel 705 may include a material having a lattice matching with the first channel 215. The second channel 705 may include, e.g., GaZn₂O₄(GZO), ZnIn₂O₄, Zn₂SnO₄, Zn₂TiO₄, Ga₂O₃, TIN, SiC, RuO₂, ZnAl₂O₄ etc.

In example embodiments, a cross-section in the first direction D1 of the second channel 705 on the first channel 215 may have a cup shape, as the cross-section of the first channel 215.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1. A semiconductor device comprising:
a bit line on a substrate;
a gate electrode on the bit line;
a gate insulation pattern on a sidewall of the gate electrode;
a first channel contacting an upper surface of the bit line and a sidewall of the gate insulation pattern, the first channel including spinel IGZO; and
a contact plug contacting an upper surface of the first channel.

2. The semiconductor device according to claim 1, further comprising a second channel on the first channel, the second channel including a material having a lattice matching with IGZO.

3. The semiconductor device according to claim 2, wherein the second channel includes at least one of GaZn₂O₄(GZO), ZnIn₂O₄, Zn₂SnO₄, Zn₂TiO₄, Ga₂O₃, TiN, SiC, RuO₂ and ZnAl₂O₄.

4. The semiconductor device according to claim 3, wherein the SECOND CHANNEL INCLUDES GAZN₂O₄(GZO).

5. The semiconductor device according to claim 2, wherein an upper surface of the second channel contacts the contact plug.

6. The semiconductor device according to claim 2, wherein an upper surface of the second channel is coplanar with the upper surface of the first channel.

7. The semiconductor device according to claim 1, wherein a cross-section in a direction of the first channel has a shape of a cup.

8. The semiconductor device according to claim 1, wherein the first channel has a top surface lower than an upper surface of the gate insulation pattern.

9. The semiconductor device according to claim 1, wherein the contact plug has a lower portion and an upper portion, the lower portion contacting the upper surface of the first channel and having a first width, and the upper portion being disposed on the lower portion and having a second width that is greater than the first width.

10. The semiconductor device according to claim 1, further comprising a capacitor on the contact plug.

11. A semiconductor device comprising:
a bit line on a substrate;
a gate electrode on the bit line;
a gate insulation pattern on a sidewall of the gate electrode;
a channel structure including:
a first channel contacting an upper surface of the bit line and a sidewall of the gate insulation pattern, the first channel including spinel IGZO; and
a second channel on the first channel, the second channel including a material having a lattice matching with IGZO; and
a contact plug contacting an upper surface of the channel structure.

12. The semiconductor device of claim 11, wherein the second channel includes at least one of GaZn₂O₄(GZO), ZnIn₂O₄, Zn₂SnO₄, Zn₂TiO₄, Ga₂O₃, TiN, SiC, RuO₂ and ZnAl₂O₄.

13. The semiconductor device of claim 12, wherein the second channel includes GaZn₂O₄(GZO).

14. The semiconductor device according to claim 11, wherein an upper surface of the second channel is coplanar with an upper surface of the first channel.

15. The semiconductor device according to claim 11, wherein a cross-section in a direction of each of the first channel and the second channel has a shape of a cup.

16. The semiconductor device according to claim 11, wherein the channel structure has a top surface lower than an upper surface of the gate insulation pattern.

17. A semiconductor device comprising:
bit lines on a substrate, each of the bit lines extending in a first direction substantially parallel to an upper surface of the substrate, and the bit lines being spaced apart from each other in a second direction, which is substantially parallel to the upper surface of the substrate and intersects the first direction;
gate electrodes on the bit lines, each of the gate electrodes extending in the second direction, and the gate electrodes being spaced apart from each other in the first direction;
a gate insulation pattern on a sidewall in the first direction of each of the gate electrodes;
a channel contacting an upper surface of each of the bit lines and a sidewall in the first direction of the gate insulation pattern, the channel including an amorphous oxide semiconductor material;
a first channel contacting an upper portion of a sidewall of the channel in the first direction, the first channel including spinel IGZO;
a contact plug contacting an upper surface of the first channel; and
a capacitor on the contact plug.

18. The semiconductor device according to claim 17, further comprising a second channel on the first channel, the second channel including GaZn₂O₄(GZO).

19. The semiconductor device according to claim 18, wherein an upper surface of the second channel contacts the contact plug.

20. The semiconductor device according to claim 17, wherein the contact plug has a lower portion and an upper portion, the lower portion contacting the upper surface of the first channel and having a first width, and the upper portion being disposed on the lower portion and having a second width that is greater than the first width.

21. (canceled)
